(19) United States
(12) Patent Application Publication
(10) Pub. No.: US 2005/0247668 A1
(43) Pub. Date: Nov. 10, 2005

(54) Method for smoothing a film of material using a ring structure

(75) Inventors: Igor J. Malik, Palo Alto, CA (US); Francois J. Henley, Aptos, CA (US); Harry R. Kirk, Campbell, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Silicon Genesis Corporation, San Jose, CA (US)

(21) Appl. No.: 10/841,253

(22) Filed: May 6, 2004

(51) Int. Cl. H01L 21/302; B44C 1/22

(52) U.S. Cl. 216/58; 216/74; 216/79; 438/706

(57) ABSTRACT

A method for treating a surface region having a surface roughness, e.g., 0.3-30 nm rms. The method includes providing a substrate, which has a surface region, a thickness of material, and a backside surface. The surface region is characterized by a first predetermined surface roughness value. The thickness of material is defined between the surface region and the backside surface. The method includes maintaining the substrate on a susceptor from the backside surface to hold the substrate in place within a treatment chamber. The method includes maintaining the surface region within an annular region, which is substantially a similar height as the surface region. The annular region has a width surrounding the surface region. The method introduces hydrogen gas into the treatment chamber and introduces an etchant gas into the treatment chamber. The method exposes the surface region having the first predetermined surface roughness value and the width of the annular region to at least the hydrogen gas and the etchant gas. The method reduces the predetermined surface roughness value from the predetermined surface roughness value to a second predetermined surface roughness value from a first edge of the substrate to a second edge of the substrate along the surface region, whereupon the reducing occurs substantially evenly across the first edge of the substrate to the second edge of the substrate.

### BACKGROUND OF THE INVENTION

The present invention relates to the manufacture of objects. More particularly, the present invention provides a technique for improving surface texture or surface characteristics of a film of material, e.g., silicon, germanium, strained silicon, silicon germanium, or others. The present invention can be applied to treating or smoothing a film of material for the manufacture of integrated circuits, for example. But it will be recognized that the invention has a wider range of applicability; it can also be applied to smoothing a film for other substrates such as multi-layered integrated circuit devices, three-dimensional packaging of integrated semiconductor devices, photonic devices, piezoelectronic devices, microelectromechanical systems (“MEMS”), sensors, actuators, solar cells, flat panel displays (e.g., LCD, AMLCD), doping semiconductor devices, biological and biomedical devices, and the like.

Integrated circuits are fabricated on chips of semiconductor material. These integrated circuits often contain thousands, or even millions, of transistors and other devices. In particular, it is desirable to put as many transistors as possible within a given area of semiconductor because more transistors typically provide greater functionality, and a smaller chip means more chips per wafer and lower costs. Some integrated circuits are fabricated on a slice or wafer, of single-crystal (monocrystalline) silicon, commonly termed a “bulk” silicon wafer. Devices on such “bulk” silicon wafer typically are isolated from each other. A variety of techniques have been proposed or used to isolate these devices from each other on the bulk silicon wafer, such as a local oxidation of silicon (“LOCOS”) process, trench isolation, and others. These techniques, however, are not free from limitations. For example, conventional isolation techniques consume a considerable amount of valuable wafer surface area on the chip, and often generate a non-planar surface as an artifact of the isolation process. Either or both of these considerations generally limit the degree of integration achievable in a given chip. Additionally, trench isolation often requires a process of reactive ion etching, which is extremely time consuming and can be difficult to achieve accurately.

An approach to achieving very-large scale integration (“VLSI”) or ultra large scale integration (“ULSI”) is by using a semiconductor-on-insulator (“SOI”) wafer. An SOI wafer typically has a layer of silicon on top of a layer of an insulator material. A variety of techniques has been proposed or used for fabricating the SOI wafer. These techniques include, among others, growing a thin layer of silicon on a sapphire substrate, bonding a layer of silicon to an insulating substrate, and forming an insulating layer beneath a silicon layer in a bulk silicon wafer. In an SOI integrated circuit, essentially complete device isolation is often achieved using conventional device processing methods by surrounding each device, including the bottom of the device, with an insulator. An advantage SOI wafers have over bulk silicon wafers is that the area required for isolation between devices on an SOI wafer is less than the area typically required for isolation on a bulk silicon wafer.

SOI offers other advantages over bulk silicon technologies as well. For example, SOI offers a simpler fabrication sequence compared to a bulk silicon wafer. Devices fabricated on an SOI wafer may also have better radiation resistance, less photo-induced current, and less cross-talk than devices fabricated on bulk silicon wafers. Many problems, however, that have already been solved regarding fabricating devices on bulk silicon wafers remain to be solved for fabricating devices on SOI wafers.

For example, SOI wafers generally must also be polished to remove any surface irregularities from the film of silicon overlying the insulating layer. Polishing generally includes, among others, chemical mechanical polishing, commonly termed CMP. CMP is generally time consuming and expensive, and can be difficult to perform cost efficiently to remove surface non-uniformities. That is, a CMP machine is expensive and requires large quantities of slurry mixture, which is also expensive. The slurry mixture can also be highly acidic or caustic. Accordingly, the slurry mixture can influence functionality and reliability of devices that are fabricated on the SOI wafer.

A pioneering technique has been developed to smooth films of materials without using CMP in certain cases. This technique relies upon use of hydrogen bearing gases and elevated temperatures to smooth films of materials. An example of such technique has been described in U.S. Pat. No. 6,171,965, commonly assigned, and hereby incorporated by reference for all purposes. Although this technique has improved CMP-related problems, other limitations still exist.

From the above, it is seen that an improved technique for manufacturing a substrate such as an SOI wafer is highly desirable.

### BRIEF SUMMARY OF THE INVENTION

According to the present invention, a technique for treating a film of material is provided. More particularly, the present invention provides a technique for improving surface texture or surface characteristics of a film of material, e.g., silicon, germanium, strained silicon, silicon germanium, or others. The present invention can be applied to treating or smoothing a film of material for the manufacture of integrated circuits, for example. But it will be recognized that the invention has a wider range of applicability; it can also be applied to smoothing a film for other substrates such as multi-layered integrated circuit devices, three-dimensional packaging of integrated semiconductor devices, photonic devices, piezoelectronic devices, microelectromechanical systems (“MEMS”), sensors, actuators, solar cells, flat panel displays (e.g., LCD, AMLCD), doping semiconductor devices, biological and biomedical devices, and the like.

In a specific embodiment, the present invention provides a method for treating a surface region having a surface roughness, e.g., 0.3-3 nm rms (as measured by AFM over 10×10 micron area). The method includes providing a substrate, which has a surface region, a thickness of material, and a backside surface. The surface region is characterized by a first predetermined surface roughness value. The thickness of material is defined between the surface region and the backside surface. The method includes maintaining the substrate on a susceptor from the backside surface to hold the substrate in place within a treatment chamber. The method includes maintaining the surface region within an annular region, which is substantially a similar height as the surface region. The annular region has a width surrounding the surface region. The method introduces hydrogen gas into the treatment chamber and introduces an etchant gas into the treatment chamber. The method exposes the surface region having the first predetermined surface roughness value and the width of the annular region to at least the hydrogen gas and the etchant gas. The method reduces the predetermined surface roughness value from the predetermined surface roughness value to a second predetermined surface roughness value from a first edge of the substrate to a second edge of the substrate along the surface region, whereupon the reducing occurs substantially evenly across the first edge of the substrate to the second edge of the substrate.

Numerous benefits are achieved by way of the present invention over preexisting techniques. For example, the present invention provides an efficient technique for forming a substantially uniform surface on an SOI wafer. Additionally, the substantially uniform surface is made by way of common hydrogen treatment and etching techniques, which can be found in conventional epitaxial tools. Furthermore, the present invention provides a novel uniform layer, which can be ready for the manufacture of integrated circuits. The present invention also relies upon standard fabrication gases such as HCl and hydrogen gas. In preferred embodiments, the present invention can improve bond interface integrity, improve crystal structure, and reduce defects in the substrate simultaneously during the process. In preferred embodiments, the present invention provides a system that can be implemented on conventional tools and the like. Depending upon the embodiment, one or more of these benefits is present. These and other advantages or benefits are described throughout the present specification and are described more particularly below.

These and other embodiments of the present invention, as well as its advantages and features are described in more detail in conjunction with the text below and attached Figures.

### BRIEF DESCRIPTION OF THE DRAWINGS

FIGS. 1 through 5 are simplified diagrams of a layer transfer process according to embodiments of the present invention;

FIG. 6 is a simplified top-view diagram of a cleaved film on a substrate according to an embodiment of the present invention; and

FIGS. 7 through 9 illustrate substrates according to experiments performed according to embodiments of the present invention

### DETAILED DESCRIPTION OF THE INVENTION

According to the present invention, a technique for treating a film of material is provided. More particularly, the present invention provides a technique for improving surface texture or surface characteristics of a film of material, e.g., silicon, germanium, strained silicon, silicon germanium, or others. The present invention can be applied to treating or smoothing a film of material for the manufacture of integrated circuits, for example. But it will be recognized that the invention has a wider range of applicability; it can also be applied to smoothing a film for other substrates such as multi-layered integrated circuit devices, three-dimensional packaging of integrated semiconductor devices, photonic devices, piezoelectronic devices, microelectromechanical systems (“MEMS”), sensors, actuators, solar cells, flat panel displays (e.g., LCD, AMLCD), doping semiconductor devices, biological and biomedical devices, and the like.

A process for fabricating a silicon-on-insulator substrate according to the present invention may be briefly outlined as follows:
(1) Provide a donor silicon wafer (which may be coated with a dielectric material);
(2) Define a cleave plane (e.g., by introduction of particles into the donor wafer to a selected depth to define a thickness of the film);
(3) Provide a target substrate material (which may be coated with a dielectric material);
(4) Bond the donor wafer to the target substrate material by joining the implanted face to the target substrate material;
(5) Increase global stress (or energy) within the cleave plane at a selected depth without initiating a cleaving action (optional);
(6) Provide stress (or energy) to a selected region of the bonded substrates to initiate a controlled cleaving action at the selected depth;
(7) Provide additional energy to the bonded substrates to sustain the controlled cleaving action to free the thickness of the film from the donor wafer (optional);
(8) Complete bonding of the donor wafer film to the target substrate (optional);
(9) Place target and cleaved film within an annular structure having an upper surface that is substantially the same height of the surface of the cleaved film;
(10) Maintain the surface of the cleaved film within the annular structure;
(11) Finish surface of cleaved film by etching and hydrogen treatment while the cleaved film is maintained in the annular structure;
(13) Form epitaxial layer (e.g., silicon, silicon germanium) overlying finished surface (optional); and
(14) Perform remaining steps, if necessary.

The above sequence of steps provides a method for manufacturing a multilayered substrate structure having a smooth surface according to an embodiment of the present invention. The method maintains the substrate within an annular structure or other like structure to surround a peripheral region of the substrate to finish the cleaved surface using a combination of etch and hydrogen treatment for silicon wafer, for example. Preferably, the annular structure facilitates for providing a uniform surface region on the cleaved film. This sequence of steps is merely an example and should not limit the scope of the claims defined herein. Further details with regard to the above sequence of steps are described in below in references to the Figures.

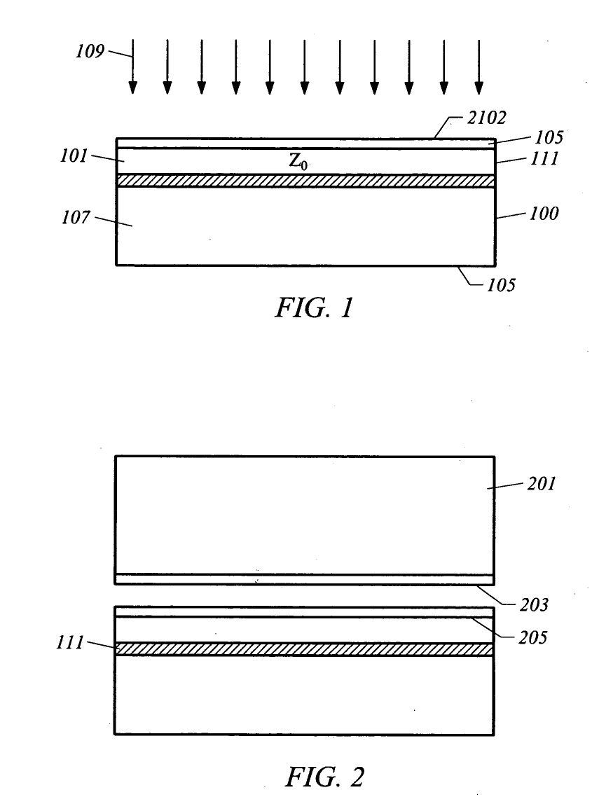

FIGS. 1-5 are simplified cross-sectional view diagrams of substrates undergoing a fabrication process for a silicon-on-insulator wafer according to the present invention. The process begins by providing a semiconductor substrate similar to the silicon wafer 100, as shown by FIG. 1. Substrate or donor includes a material region 101 to be removed, which is a thin, relatively uniform film derived from the substrate material. The silicon wafer includes a top surface 103, a bottom surface 105, and a thickness 107. Material region also includes a thickness (z₀), within the thickness 107 of the silicon wafer. Optionally, a dielectric layer 102 (e.g., silicon nitride, silicon oxide, silicon oxynitride) overlies the top surface of the substrate. The present process provides a technique for removing the material region 101 using the following sequence of steps for the fabrication of a silicon-on-insulator wafer.

Selected energetic particles 109 implant through the top surface of the silicon wafer to a selected depth (cleave plane formation), which defines the thickness of the material region, termed the thin film of material. As shown, the particles have a desired concentration 111 at the selected depth (z₀). A variety of techniques can be used to implant the energetic particles into the silicon wafer. These techniques include ion implantation using, for example, beam line ion implantation equipment manufactured from companies such as Applied Materials, Eaton Corporation, Varian, and others. Alternatively, implantation occurs using a plasma immersion ion implantation (“Pill”) technique. Furthermore, implantation can occur using ion shower. Of course, techniques used depend upon the application.

Depending upon the application, smaller mass particles are generally selected to reduce a possibility of damage to the material region. That is, smaller mass particles easily travel through the substrate material to the selected depth without substantially damaging the material region that the particles traversed through. For example, the smaller mass particles (or energetic particles) can be almost any charged (e.g., positive or negative) and/or neutral atoms or molecules, or electrons, or the like. In a specific embodiment, the particles can be neutral and/or charged particles including ions of hydrogen and its isotopes, rare gas ions such as helium and its isotopes, and neon. The particles can also be derived from compounds such as gases, e.g., hydrogen gas, water vapor, methane, and other hydrogen compounds, and other light atomic mass particles. Alternatively, the particles can be any combination of the above particles, and/or ions and/or molecular species and/or atomic species.

The process uses a step ofjoining the implanted silicon wafer to a workpiece or target wafer, as illustrated in FIG. 2. The workpiece may also be a variety of other types of substrates such as those made of a dielectric material (e.g., quartz, glass, silicon nitride, silicon dioxide), a conductive material (silicon, polysilicon, group III/V materials, metal), and plastics (e.g., polyimide-based materials). In the present example, however, the workpiece is a silicon wafer.

In a specific embodiment, the silicon wafers are joined or fused together using a low temperature thermal step. The low temperature thermal process generally ensures that the implanted particles do not place excessive stress on the material region, which can produce an uncontrolled cleave action. In one aspect, the low temperature bonding process occurs by a self-bonding process. In particular, one wafer is stripped to remove oxidation therefrom (or one wafer is not oxidized). A cleaning solution treats the surface of the wafer to form O—H bonds on the wafer surface. An example of a solution used to clean the wafer is a mixture of H₂O₂—H₂SO₄. A dryer dries the wafer surfaces to remove any residual liquids or particles from the wafer surfaces. Self-bonding occurs by placing a face of the cleaned wafer against the face of an oxidized wafer.

Alternatively, a self-bonding process occurs by activating one of the wafer surfaces to be bonded by plasma cleaning. In particular, plasma cleaning activates the wafer surface using a plasma derived from gases such as argon, ammonia, neon, water vapor, and oxygen. The activated wafer surface 203 is placed against a face of the other wafer, which has a coat of oxidation 205 thereon. The wafers are in a sandwiched structure having exposed wafer faces. A selected amount of pressure is placed on each exposed face of the wafers to self-bond one wafer to the other.

Alternatively, an adhesive disposed on the wafer surfaces is used to bond one wafer onto the other. The adhesive includes an epoxy, polyimide-type materials, and the like. Spin-on-glass layers can be used to bond one wafer surface onto the face of another. These spin-on-glass (“SOG”) materials include, among others, siloxanes or silicates, which are often mixed with alcohol-based solvents or the like. SOG can be a desirable material because of the low temperatures (e.g., 150 to 250 Degrees Celsius) often needed to cure the SOG after it is applied to surfaces of the wafers.

Alternatively, a variety of other low temperature techniques can be used to join the donor wafer to the target wafer. For instance, an electro-static bonding technique can be used to join the two wafers together. In particular, one or both wafer surface(s) is charged to attract to the other wafer surface. Additionally, the donor wafer can be fused to the target wafer using a variety of commonly known techniques. Of course, the technique used depends upon the application.

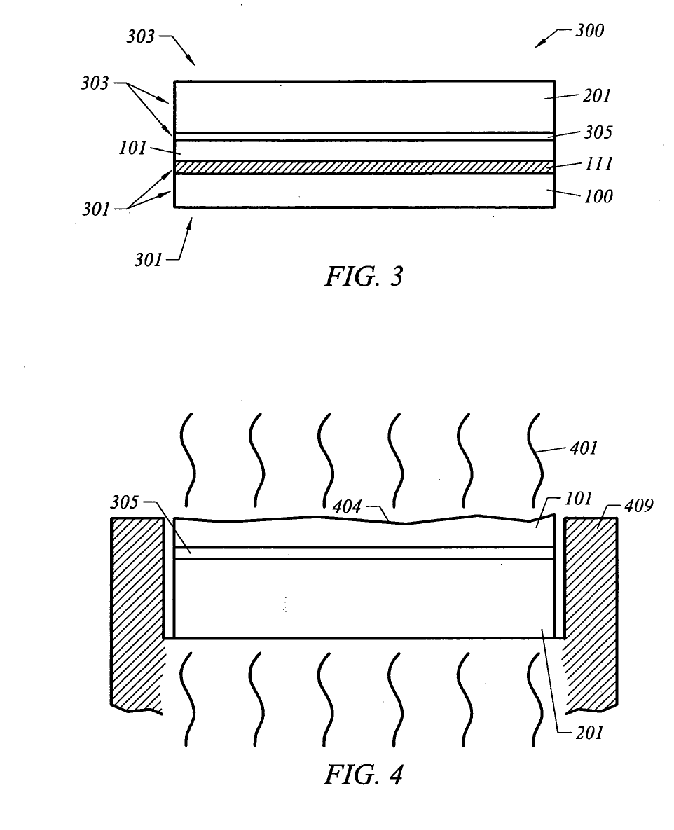

After bonding the wafers into a sandwiched structure 300, as shown in FIG. 3, the method includes a controlled cleaving action to remove the substrate material to provide a thin film of substrate material 101 overlying an insulator 305 the target silicon wafer 201. The controlled-cleaving occurs by way of selective energy placement or positioning or targeting 301, 303 of energy sources onto the donor and/or target wafers. For instance, an energy impluse(s) can be used to initiate the cleaving action. The impulse (or impulses) is provided using an energy source which include, among others, a mechanical source, a chemical source, a thermal sink or source, and an electrical source.

The controlled cleaving action is initiated by way of any of the previously noted techniques and others and is illustrated by way of FIG. 3. For instance, a process for initiating the controlled cleaving action uses a step of providing energy 301, 303 to a selected region of the substrate to initiate a controlled cleaving action at the selected depth (z₀) in the substrate, whereupon the cleaving action is made using a propagating cleave front to free a portion of the substrate material to be removed from the substrate. In a specific embodiment, the method uses a single impulse to begin the cleaving action, as previously noted. Alternatively, the method uses an initiation impulse, which is followed by another impulse or successive impulses to selected regions of the substrate. Alternatively, the method provides an impulse to initiate a cleaving action which is sustained by a scanned energy along the substrate. Alternatively, energy can be scanned across selected regions of the substrate to initiate and/or sustain the controlled cleaving action.

Optionally, an energy or stress of the substrate material is increased toward an energy level necessary to initiate the cleaving action, but not enough to initiate the cleaving action before directing an impulse or multiple successive impulses to the substrate according to the present invention. The global energy state of the substrate can be raised or lowered using a variety of sources such as chemical, mechanical, thermal (sink or source), or electrical, et al. These sources can also include chemical reaction to increase stress in the material region. The chemical source is introduced as flood, time-varying, spatially varying, or continuous. In other embodiments, a mechanical source is derived from rotational, translational, compressional, expansional, or ultrasonic energies. The mechanical source can be introduced as flood, time-varying, spatially varying, or continuous. In further embodiments, the electrical source is selected from an applied voltage or an applied electromagnetic field, which is introduced as flood, time-varying, spatially varying, or continuous. In still further embodiments, the thermal source or sink is selected from radiation, convection, or conduction. This thermal source can be selected from, among others, a photon beam, a fluid jet, a liquid jet, a gas jet, an electromagnetic field, an electron beam, a thermoelectric heating, and a furnace. The thermal sink can be selected from a fluid jet, a liquid jet, a gas jet, a cryogenic fluid, a super-cooled liquid, a thermo-electric cooling means, an electro/magnetic field, and others. Similar to the previous embodiments, the thermal source is applied as flood, time-varying, spatially varying, or continuous. Still further, any of the above embodiments can be combined or even separated, depending upon the application. Of course, the type of source used depends upon the application. As noted, the global source increases a level of energy or stress in the material region without initiating a cleaving action in the material region before providing energy to initiate the controlled cleaving action.

In a preferred embodiment, the method maintains a temperature which is below a temperature of introducing the particles into the substrate. In some embodiments, the substrate temperature is maintained between −200 and 450 Degrees Celsius during the step of introducing energy to initiate propagation of the cleaving action. Substrate temperature can also be maintained at a temperature below 400 or below 350 Degrees Celsius. In preferred embodiments, the method uses a thermal sink to initiate and maintain the cleaving action, which occurs at conditions significantly below room temperature.

In an alternative preferred embodiment, the mechanical and/or thermal source can be a fluid jet that is pressurized (e.g., compressional) according to an embodiment of the present invention. The fluid jet (or liquid jet or gas jet) impinges on an edge region of substrate 300 to initiate the controlled cleaving process. The fluid jet from a compressed or pressurized fluid source is directed to a region at the selected depth 111 to cleave a thickness of material region 101 from substrate 100. The fluidjet separates region 101 from substrate 100 that separate from each other at selected depth 111. The fluid jet can be adjusted to initiate and maintain the controlled cleaving process to separate material 101 from substrate 100. Depending upon the application, the fluid jet can be adjusted in direction, location, and magnitude to achieve the desired controlled cleaving process.

A final bonding step occurs between the target wafer and thin film of material region according to some embodiments, as illustrated by FIG. 4. In one embodiment, one silicon wafer has an overlying layer of silicon dioxide, which is thermally grown overlying the face before cleaning the thin film of material. The silicon dioxide can also be formed using a variety of other techniques, e.g., chemical vapor deposition. The silicon dioxide between the wafer surfaces fuses together thermally in this process.

In some embodiments, the oxidized silicon surface from either the target wafer or the thin film of material region (from the donor wafer) are further pressed together and are subjected to an oxidizing ambient 401. The oxidizing ambient can be in a diffusion furnace for steam oxidation, or the like. A combination of the pressure and the oxidizing ambient fuses the two silicon wafers together at the oxide surface or interface 305. These embodiments often require high temperatures (e.g., 700 Degrees Celsius).

Alternatively, the two silicon surfaces are further pressed together and subjected to an applied voltage between the two wafers. The applied voltage raises temperature of the wafers to induce a bonding between the wafers. This technique limits the amount of crystal defects introduced into the silicon wafers during the bonding process, since substantially no mechanical force is needed to initiate the bonding action between the wafers. Of course, the technique used depends upon the application.

After bonding the wafers, silicon-on-insulator has a target substrate with an overlying film of silicon material and a sandwiched oxide layer between the target substrate and the silicon film, as also illustrated in FIG. 4. The detached surface of the film of silicon material is often rough 404 and needs finishing. The rough surface for silicon wafers is often about two to eight nanometers RMS or greater. This roughness often should be removed before further processing. In a specific embodiment, the detached surface has a concentration of hydrogen bearing particles therein and thereon from the previous implanting step.

To smooth or treat surface 404, the substrate is subjected to thermal treatment 401 in a hydrogen bearing environment. Additionally, the substrate is also subjected to an etchant including a halogen bearing compound such as HCl, HBr, HI, HF, and others. The etchant can also be a fluorine bearing compound such as SF₆, Cₓ Fₓ.

In preferred embodiments, the present substrate undergoes treatment using a combination of etchant and thermal treatment in a hydrogen bearing environment. In a specific embodiment, the etchant is HCl gas or the like. The thermal treatment uses hydrogen gas. In some embodiments, the etchant gas is a halogenated gas, e.g., HCl, HF, HI, HBr, SF₆, CF₄, NF₃, and CCl₂ F₂. The etchant gas can also be mixed with another halogen gas, e.g., chlorine, fluorine. The thermal treatment can be from a furnace, but is preferably from a rapid thermal processing tool such as an RTP tool. Alternatively, the tool can be from an epitaxial chamber, which has lamps for rapidly heating a substrate. In an embodiment using a silicon wafer and hydrogen gas, the tool can heat the substrate at a rate of about 10 Degrees Celsius and greater or 20 Degrees Celsius and greater, depending upon the embodiment.

In one embodiment, it is believed that the hydrogen particles in the detached surface improve the surface smoothing process. Here, the hydrogen particles have been maintained at a temperature where they have not diffused out of the substrate. In a specific embodiment, the concentration of hydrogen particles ranges from about 10²¹ to about 5 times 10²² atoms/cm³. Alternatively, the concentration of hydrogen particles is at least about 6 times 10²¹ atoms/cm³. Depending upon the embodiment, the particular concentration of the hydrogen particles can be adjusted.

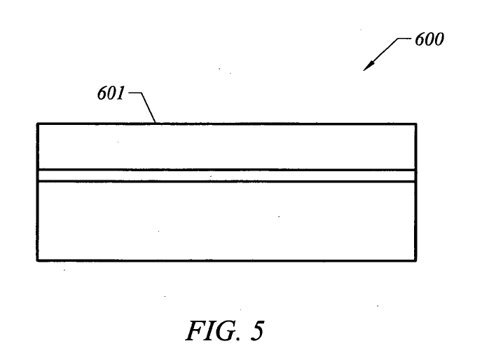

Still further in other embodiments, the present substrate undergoes a process of hydrogen treatment or implantation before thermal treatment purposes. Here, the substrate, including the detached film, is subjected to hydrogen bearing particles by way of implantation, diffusion, or any combination thereof. In some embodiments, where hydrogen has diffused out from the initial implant, a subsequent hydrogen treatment process can occur to increase a concentration of hydrogen in the detached film. The present hydrogen treatment process can occur for substrates made by way of the controlled cleaving process, Smart Cut™ process of Soitec SA, and others, which may form an uneven or rough surface finish after detachment. A finished wafer after smoothing or surface treatment is shown in FIG. 5. Here, the finished wafer includes a substantially smooth surface 601, which is generally good enough for the manufacture of integrated circuits without substantial polishing or the like.

Moreover, the present technique for finishing the cleaved surface can use a combination of etchant, deposition, and thermal treatment to smooth the cleaved film. Here, the cleaved film is subjected to hydrogen bearing compounds such as HCl, HBr, HI, HF, and others. Additionally, the cleaved film is subjected to for example, deposition, during a time that the film is subjected to the hydrogen bearing compounds, which etch portions of the cleaved film. Using a silicon cleaved film for example, the deposition may occur by way of a silicon bearing compound such as silanes, e.g., Siₓ Cl_{y} H_{z}, SiH₄, SiClₓ, and other silicon compounds. Accordingly, the present method subjects the cleaved film to a combination of etching and deposition using a hydrogen bearing compound and a silicon bearing compound. Additionally, the cleaved surface undergoes thermal treatment while being subjected to the combination of etchant and deposition gases. The thermal treatment can be from a furnace, but is preferably from a rapid thermal processing tool such as an RTP tool. Alternatively, the tool can be from an epitaxial chamber, which has lamps for rapidly heating a substrate. In an embodiment using a silicon wafer and hydrogen gas, the tool can heat the substrate at a rate of about 10 Degrees Celsius/second and greater or 20 Degrees Celsius/second and greater, depending upon the embodiment. In some embodiments, the process is also maintained at about 1 atmosphere, but is not limited to this pressure.

Preferably, the method includes maintaining the surface region within an annular region 409, which is substantially a similar height as the surface region. The annular region has a width surrounding the surface region. The annular region is made of the same or similar material as the surface region or substrate. The annular region can be solid or multilayered, which includes a coating similar or the same as the surface region of the substrate. The annular region has a width of about 1-10 cm and surrounds a peripheral region of the substrate. The annular region has an etching and/or smoothing characteristic similar to a center region of the substrate. The method then introduces hydrogen gas into the treatment chamber and introduces an etchant gas into the treatment chamber. The method exposes the surface region having the first predetermined surface roughness value and the width of the annular region to at least the hydrogen gas and the etchant gas. The method reduces the predetermined surface roughness value from the predetermined surface roughness value to a second predetermined surface roughness value from a first edge of the substrate to a second edge of the substrate along the surface region, whereupon the reducing occurs substantially evenly across the first edge of the substrate to the second edge of the substrate.

In a specific embodiment, the silicon-on-insulator substrate undergoes a series of process steps for formation of integrated circuits thereon. These processing steps are described in S. Wolf, Silicon Processing for the VLSI Era (Volume 2), Lattice Press (1990), which is hereby incorporated by reference for all purposes.

Although the above has been described in terms of specific embodiments, other variations, modifications, and alternatives can be achieved. For example, the cleaved film can be any film such as any rough film, e.g., SIMOX, Smart Cut™, ELTRAN™, etc. The film can also be an epitaxial grown film that is free from cleaving, an unpolished or incompletely polished substrate. Of course, there can be various modifications,

Experiments:

To prove the principles and operation of the present invention, experiments were performed. These experiments are merely examples, and should not unduly limit the scope of the claims herein. One of ordinary skill in the art would recognize many variations, alternatives, and modifications. These experiments can use an Applied Materials Epi Centura or an ASM Epsilon Epi tool. The process can be performed at atmospheric pressure or reduced pressure.

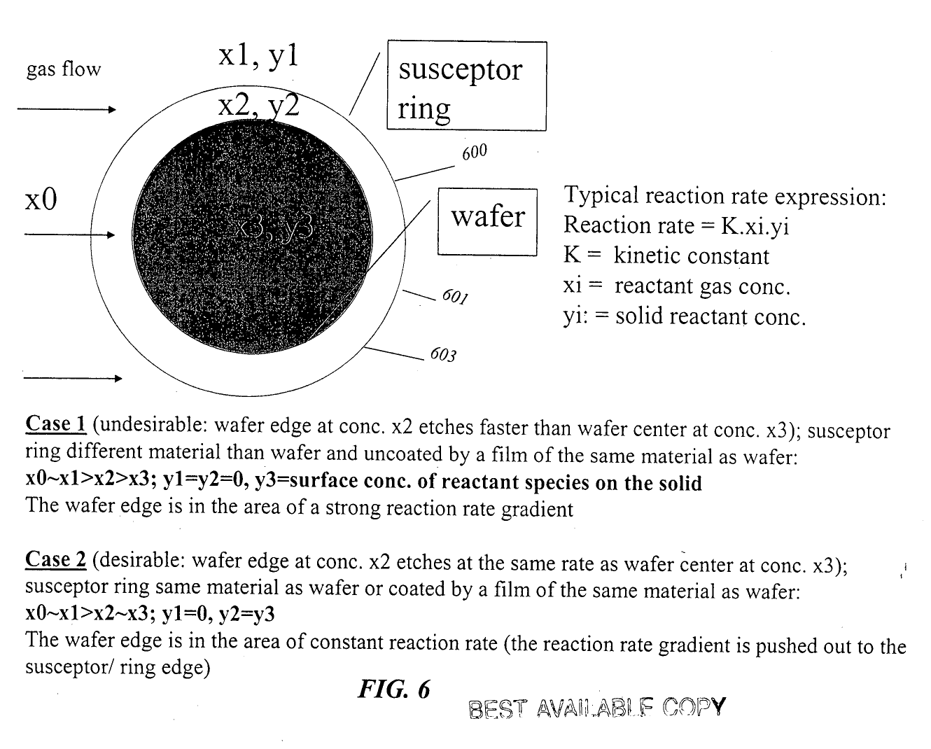

Referring to FIG. 6, the method includes a substrate 603 placed within a ring structure 601. The ring structure is made of a similar or the same material as the substrate. That is, the top surface of the substrate is made of the same or similar material as the top surface of the ring structure. The height of the ring structure is substantially the same as the height of the top surface. A spacing between the ring structure and the substrate is preferably less than about 2 mm, but can be other dimensions. A common reaction rate is characterized as follows:
Reaction Rate=Kx(i)y(i)
where K=kinetic constant;
x(i)=reaction gas concentration; and
y(i)=solid reactant concentration.
   As shown under case 1, which is generally undesirable, the wafer edge is at a higher concentration of etchant and etches faster than a center region of the wafer. Here, the ring may be of a different material than the wafer or no ring exist surrounding the wafer. As shown under case 2, which is desirable, the wafer edge is at a concentration of etchant that is substantially the same as the center region. The ring material is made of or is coated with the same or similar type of material as the wafer. That is, the reaction rate is substantially constant from end to end. Preferably, the width of the ring is selected such that the reaction rate across the entire surface of the substrate is substantially constant.

Examples of specific process conditions are provided as follows:
1. Process conditions range for SOI:
   Temperature 950-1250 C, preferably 1050-1150 C
   HCl conc. 0.01%-5% (mole %)
   Susceptor coating: Si
2. Process conditions range for GeOI:
   Temperature 550-850 C, preferably 700-800 C
   HCl conc. 0.01%-5% (mole %)
   Susceptor coating: Ge or SiGe

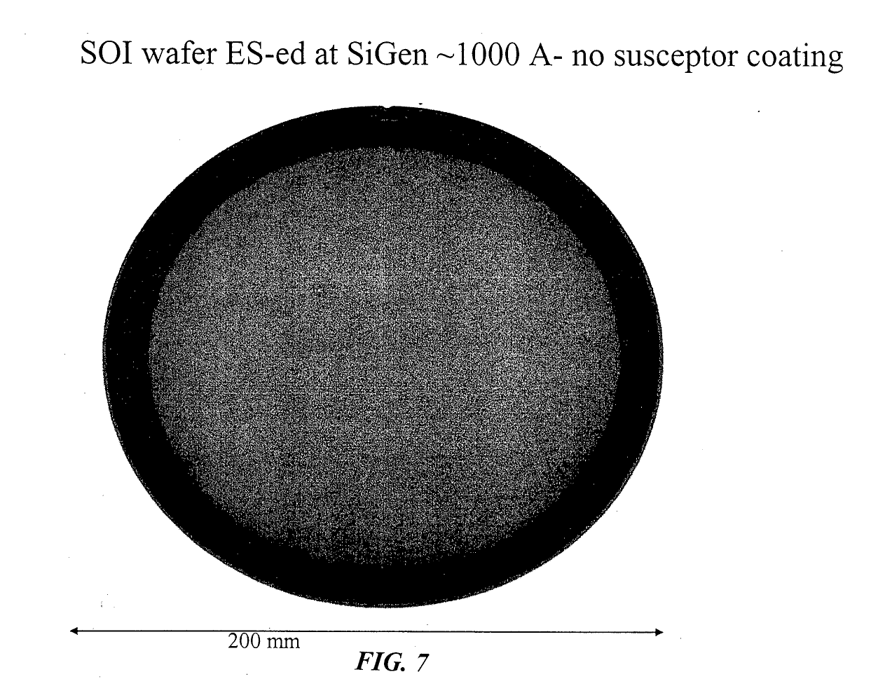

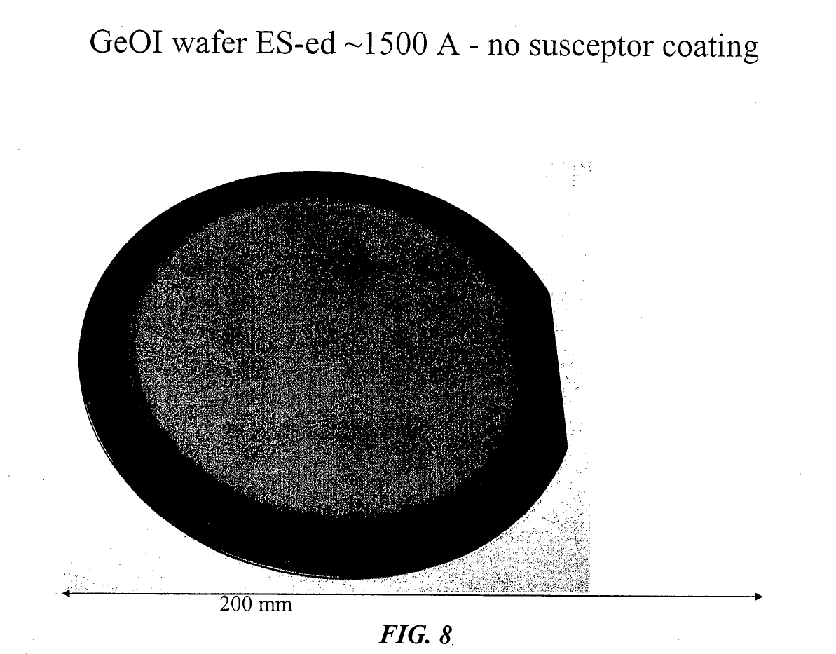

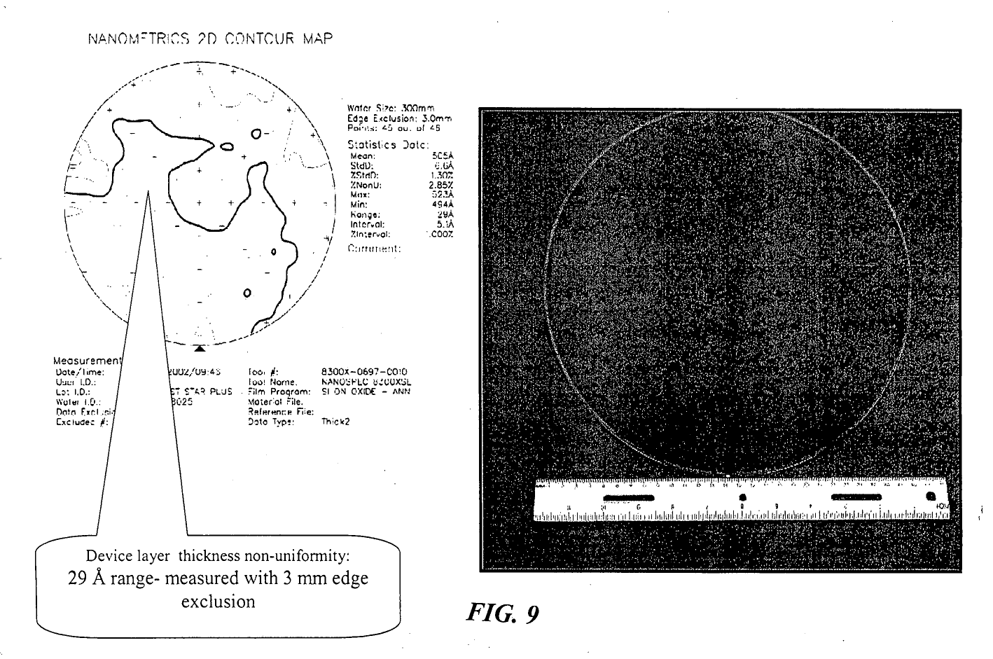

Of course, there can be other variations modifications, and alternatives. Examples of wafers subjected to conventional processes are illustrated by way of the simplified diagrams of FIGS. 7 and 8. As shown, the edge region of the wafers are not uniform and may vary greater than about 1000 Angstroms. An example of a smoothed wafer according to an embodiment of the present invention is illustrated by the simplified diagram of FIG. 9. As shown, the non-uniformity is about 29 Angstroms with a 3 millimeter edge exclusion region. The smoothed wafer has a length of 300 millimeters and is an SOI water made using a cleaving process such as the one described above, but can be others.

Although the above description is in terms of a silicon wafer, other substrates may also be used. For example, the substrate can be almost any monocrystalline, polycrystalline, or even amorphous type substrate. Additionally, the substrate can be made of IIIV materials such as gallium arsenide, gallium nitride (GaN), silicon germanium alloy, germanium, silicon carbon alloy, II-VI materials, strained silicon, and others. The multi-layered substrate can also be used according to the present invention. The multi-layered substrate includes a silicon-on-insulator substrate, a variety of sandwiched layers on a semiconductor substrate, and numerous other types of substrates. Additionally, the embodiments above were generally in terms of providing a pulse of energy to initiate a controlled cleaving action. The pulse can be replaced by energy that is scanned across a selected region of the substrate to initiate the controlled cleaving action. Energy can also be scanned across selected regions of the substrate to sustain or maintain the controlled cleaving action. One of ordinary skill in the art would easily recognize a variety of alternatives, modifications, and variations, which can be used according to the present invention.

It is also understood that the examples and embodiments described herein are for illustrative purposes only and that various modifications or changes in light thereof will be suggested to persons skilled in the art and are to be included within the spirit and purview of this application and scope of the appended claims.

1. A method for treating a surface region having a surface roughness, the method comprising:
providing a substrate having a surface region, a thickness of material, and a backside surface, the surface region being characterized by a first predetermined surface roughness value, the thickness of material being defined between the surface region and the backside surface;
maintaining the substrate on a susceptor from the backside surface to hold the substrate in place within a treatment chamber;
maintaining the surface region within an annular region, the annular region being at substantially a similar height as the surface region, the annular region having a width surrounding the surface region;
introducing hydrogen gas into the treatment chamber;
introducing HCl gas into the treatment chamber;
exposing the surface region having the first predetermined surface roughness value and the width of the annular region to at least the hydrogen gas and the HCl gas; and
reducing the predetermined surface roughness value from the predetermined surface roughness value to a second predetermined surface roughness value from a first edge region of the substrate to a second edge region of the substrate along the surface region, whereupon the reducing occurs substantially evenly across the first edge region of the substrate to the second edge region of the substrate.

2. The method of claim 1 wherein the substrate comprises a silicon wafer.

3. The method of claim 1 wherein the annular region is a ring structure.

4. The method of claim 1 wherein the width ranges from about 1 to about 10 centimeters.

5. The method of claim 1 wherein the annular region is made of a first material and the substrate is made of a second material, the first material being similar to the second material.

6. The method of claim 1 wherein the substrate is made of silicon and the annular region is made of silicon.

7. The method of claim 1 wherein the annular region comprises a silicon ring structure.

8. The method of claim 1 wherein the annular region evenly distributes the hydrogen gas and the HCl gas along the surface region from the first edge of the substrate to the second edge of the substrate.

9. The method of claim 8 wherein the annular region reduces a fringe influence within a perimeter of the substrate, the perimeter being defined by the first edge and the second edge.

10. The method of claim 1 wherein the surface region comprises materials selected from silicon, germanium, silicon germanium alloy, and silicon germanium carbon alloy.

11. A method for treating a surface region having a surface roughness, the method comprising:
providing a substrate having a surface region, a thickness of material, and a backside surface, the surface region being characterized by a first predetermined surface roughness value, the thickness of material being defined between the surface region and the backside surface;
maintaining the substrate on a susceptor from the backside surface to hold the substrate in place within a treatment chamber;
maintaining the surface region within an annular region, the annular region being at substantially a similar height as the surface region, the annular region having a width surrounding the surface region;
introducing hydrogen gas into the treatment chamber;
introducing an etchant gas into the treatment chamber;
exposing the surface region having the first predetermined surface roughness value and the width of the annular region to at least the hydrogen gas and the etchant gas; and
reducing the predetermined surface roughness value from the predetermined surface roughness value to a second predetermined surface roughness value from a first edge of the substrate to a second edge of the substrate along the surface region, whereupon the reducing occurs substantially evenly across the first edge of the substrate to the second edge of the substrate.

12. The method of claim 11 wherein the substrate comprises a silicon wafer.

13. The method of claim 11 wherein the annular region is a ring structure.

14. The method of claim 11 wherein the width ranges from about 1 to about 3 centimeters.

15. The method of claim 11 wherein the annular region is made of a first material and the substrate is made of a second material, the first material being similar to the second material.

16. The method of claim 11 wherein the substrate is made of silicon and the annular region is made of silicon.

17. The method of claim 11 wherein the annular region comprises a silicon ring structure.

18. The method of claim 11 wherein the annular region evenly distributes the hydrogen gas and the etchant gas along the surface region from the first edge of the substrate to the second edge of the substrate.

19. The method of claim 18 wherein the annular region reduces a fringe influence within a perimeter of the substrate, the perimeter being defined by the first edge and the second edge.

20. The method of claim 11 wherein the surface region comprises materials selected from silicon, germanium, silicon germanium, strained silicon, and group III/IV materials.
